(19) United States
(12) Patent Application Publication
(10) Pub. No.: US 2026/0329320 A1
(43) Pub. Date: Oct. 22, 2026

(54) DEVICE FOR OPTIMIZING NOISE AT AN OUTPUT OF HIGH VOLTAGE LOW-DROPOUT REGULATOR

(71) Applicant: Samsung Electronics Co., Ltd., Suwon-si, (KR)

(72) Inventors: Zaira ZAHIR, Bengaluru (IN); Deepa DEVENDRAN, Bengaluru (IN)

(73) Assignee: Samsung Electronics Co., Ltd., Suwon-si (KR)

(21) Appl. No.: 19/381,298

(22) Filed: Nov. 6, 2025

(30) Foreign Application Priority Data
Apr. 22, 2025 (IN) 202541038572

(51) Int. Cl. G05F 1/575; G05F 1/46

(52) U.S. Cl. CPC G05F 1/575; G05F 1/468

(57) ABSTRACT

A device comprises a first intermediate LDO regulator configured to generate a first enhanced reference voltage, a resistor-capacitor (RC) circuit connected to the first intermediate LDO regulator, the RC circuit comprising an RC filter configured to generate a filtered reference voltage based on the first enhanced reference voltage; a second intermediate LDO regulator connected in parallel to the first intermediate LDO regulator and the RC circuit; the second intermediate LDO regulator generates a second replica enhanced reference voltage based on the input reference voltage; a low noise buffer selectively receiving one of the filtered reference voltage or the second replica enhanced reference voltage to generate a buffer reference voltage. These are configured to be transmitted to the high voltage LDO regulator based on an operational state of the RC filter. The high voltage LDO regulator is configured to generate the output based on the buffered reference voltage.

### CROSS-REFERENCE TO RELATED APPLICATION

This application is based on and claims priority under 35 U.S.C. § 119 to Indian Patent Application number 202541038572, filed on Apr. 22, 2025, in the Indian Intellectual Property Office, the disclosure of which is herein incorporated by reference in its entirety.

### BACKGROUND

Some example embodiments relate to the field of power electronics. More particularly, some example embodiments relate to a device for improving or optimizing noise at an output of a high voltage low-dropout regulator.

In modern mobile devices, laptops, and battery adapters, power management integrated circuits (PMICs) are used to efficiently manage the distribution and regulation of power to various components. PMICs often require or use high voltage converters and/or low dropout regulators (LDOs) to ensure or to help ensure that all internal circuits receive the proper voltage for optimal performance, and to handle the power needs of components like processors, sensors, radios, and displays.

A Low Dropout (LDO) regulator operates with a very small difference (or dropout voltage) between input and output voltages, which is typically in the range of 0.1V to 2V and which depends on a design of the LDO regulator. A typical LDO regulator maintains a stable and/or regulated output voltage, even when an input voltage fluctuates within a specific range. The LDO regulator operates in a linear mode, making the LDO regulator suitable for applications requiring low noise and precise voltage regulation. Conventional LDO regulators primarily have to source current capability to provide power to a load.

Further, LDOs are used at the output of the converters to reduce switching noise of the converters. However, low frequency flicker and/or thermal noise of reference chain are multiplied by feedback ratio (1/Bhv_ldo) of the LDO. Alternatively or additionally, load/line transient requirements of the PMICs also prevent or reduce bandwidth of the LDO beyond a certain point, increasing the noise at an output of the LDO. Alternatively or additionally, high voltage converters and high voltage LDOs (5V to 22V) require higher closed loop voltage gains (lower Bhv_ldo) resulting in higher output noise at the output. For wide/higher voltage range, using unity gain feedback LDOs is not feasible due to higher common mode issues. To mitigate or at least partially mitigate these concerns, many low noise bandgap architectures are present to reduce the reference noise. However, noise specification on the references becomes very stringent in case of high voltage LDO output since the feedback ratio is high. Thus, proper architecture planning is required or desired to reduce or optimize the noise at the output of the high voltage LDO.

### SUMMARY

FIG. 1 illustrates a problem associated with a conventional high-voltage low dropout regulator circuit 100. As shown, in the high-voltage low dropout (HV LDO) regulator circuit 100, a Low Noise Bandgap (LNB) circuit 102 is connected in series to a low noise buffer 104. The output of the low noise buffer 104 is used to generate reference voltages VREF2 and VREF3 using a decoder 106. The outputs of the decoder 106 provide input references to a converter 110 and an HV LDO regulator 112 (also referred to as the “HV LDO 112”), as shown in FIG. 1. The LNB circuit 102 provides a stable, clean low noise input reference voltage for the low noise buffer 104 and eventually for the HV LDO 112. Thus, the LNB circuit 102 reduces integrated noise at the HV LDO 112. The low noise bandgap references are effective for reducing noise in low voltage LDO circuits and providing stable output voltage.

However, in circuit 100, the final division ratio for the HV LDO is high, and therefore, even a small noise at VREF2 (e.g., the output of the decoder 106) is amplified. Thus, it is difficult to obtain the integrated noise (0.1 Hz to 1 GHz)<36uV rms with the conventional reference generation architecture for the HV LDO regulator.

Thus, it is desirable to address or at least partially address the above-mentioned disadvantages and/or other shortcomings of the high voltage LDO and to improve or optimize the noise at the output of high voltage LDO.

This summary is provided to introduce a selection of concepts, in a simplified format, that are further described in the detailed description of the present disclosure. This summary is neither intended to identify essential concepts of the present disclosure nor is it intended for determining the scope of the present disclosure.

According to some example embodiments, a device for improving noise at an output of a high voltage Low-Dropout (LDO) regulator is provided. The device comprises a first intermediate LDO regulator configured to generate a first enhanced reference voltage based on an input reference voltage. The device comprises a resistor-capacitor (RC) circuit connected to the first intermediate LDO regulator. The RC circuit comprises an RC filter configured to generate a filtered reference voltage based on the first enhanced reference voltage. The device comprises a second intermediate LDO regulator connected in parallel to the first intermediate LDO regulator and the RC circuit. The second intermediate LDO regulator generates a second replica enhanced reference voltage based on the input reference voltage. Further, the device comprises a low noise buffer configured to selectively receive one of the filtered reference voltage or the second replica enhanced reference voltage to generate a buffer reference voltage for the high voltage LDO regulator. The one of the filtered reference voltage or the second replica enhanced reference voltage is configured to be transmitted to the high voltage LDO regulator based on an operational state of the RC filter. The operational state of the RC filter includes one or more of a start-up state, a settling state, and a settled state. The high voltage LDO regulator is configured to generate the output based on the buffered reference voltage.

In some example embodiments, the device may further include a decoder having an input connected to an output of the low noise buffer and having a first output connected to a first input of the high voltage LDO regulator.

In some example embodiments, the decoder is configured to operate based on a 10-bit digital code.

In some example embodiments, the device may further include a converter having a first input connected to a second output of the decoder, and having an output connected to a second input of the high voltage LDO regulator.

In some example embodiments, at least one of the first switch or the second switch is a transistor.

In some example embodiments, the current mirror is configured to operate with 2uA.

In some example embodiments, each of the first intermediate LDO regulator and the second intermediate LDO regulator include an operational amplifier.

Alternatively or additionally, there is provided a method of operating a high voltage Low-Dropout (LDO) regulator, the method comprising: generating a first enhanced reference voltage based on an input reference voltage; generating a filtered reference voltage based on the first enhanced reference voltage; generating a second replica enhanced reference voltage based on the input reference voltage by using a resistor-capacitor (RC) filter; selectively receiving one of the filtered reference voltage or the second replica enhanced reference voltage; generating a buffer reference voltage for the high voltage LDO regulator; transferring one of the filtered reference voltage or the second replica enhanced reference voltage to the high voltage LDO regulator based on an operational state of the RC filter, the operational state of the RC filter including one or more of a start-up state, a settling state, or a settled state; and generating an output based on the buffer reference voltage.

In some example embodiments, the method may further include providing the input reference voltage to first and second LDO regulators included in the high voltage LDO regulator.

In some example embodiments, the method may further include filtering noise through the RC filter.

In some example embodiments, the method may further include reducing a transitional time between the start-up state and the settled state.

In some example embodiments, the method may further include turning off a first switch included in the high voltage LDO regulator to disconnect an RC circuit from a low noise buffer and turning on a second switch included in the high voltage LDO regulator to connect an intermediate LDO regulator to the low noise buffer during the start-up state of the RC filter; and turning on the first switch to connect the low noise buffer to the RC circuit and turning off the second switch to disconnect the intermediate LDO regulator form the low noise buffer during the settled state of the RC filter.

In some example embodiments, there is provided a non-transitory computer readable medium storing instructions for execution by a processor that, when executed by the processor, cause an apparatus including the processor to perform the method.

To further clarify the advantages and features of inventive concepts, description of the some example embodiments will be rendered by reference to implementations thereof, which are illustrated in the appended drawings. It is appreciated that these drawings depict only typical implementations of the present disclosure and are therefore not to be considered limiting of its scope. Some example embodiments will be described and explained with additional specificity and detail in the accompanying drawings.

### BRIEF DESCRIPTION OF THE DRAWINGS

These and other features, aspects, and advantages of some example embodiments will become better understood when the following detailed description is read with reference to the accompanying drawings in which like characters represent like parts throughout the drawings.

FIG. 1 illustrates a problem associated with a conventional high voltage low dropout regulator circuit.

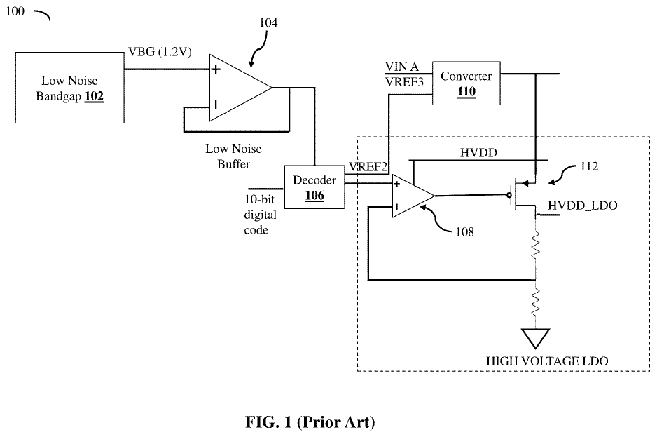

FIG. 2 illustrates a circuit diagram of a device for optimizing noise at an output of a high voltage Low-Dropout (LDO) regulator, in accordance with some example embodiments; and

FIG. 3 illustrates a startup circuit, in accordance with some example embodiments.

Further, those of ordinary skill in the art will appreciate that elements in the drawings are illustrated for simplicity and may not have necessarily been drawn to scale. For example, the flow charts illustrate the method in terms of the most prominent steps involved to help improve understanding of aspects of the present disclosure. Furthermore, in terms of the construction of the device, one or more components of the device may have been represented in the drawings by conventional symbols, and the drawings may show only those specific details that are pertinent to understanding the implementations of the present disclosure so as not to obscure the drawings with details that will be readily apparent to those of ordinary skill in the art having the benefit of the description herein.

### DETAILED DESCRIPTION

For the purpose of promoting an understanding of the principles of the present disclosure, reference will now be made to the implementation illustrated in the drawings and specific language will be used to describe the same. It will nevertheless be understood that no limitation of the scope of example embodiments is thereby intended, such alterations and further modifications in the illustrated system, and such further applications of the principles of the present disclosure as illustrated therein being contemplated as would normally occur to one skilled in the art to which the present disclosure relates.

It will be understood by those of ordinary skill in the art that the foregoing general description and the following detailed description are explanatory of the present disclosure and are not intended to be restrictive thereof.

Reference throughout this specification to “an aspect”, “another aspect” or similar language means that a particular feature, structure, or characteristic described in connection with the implementation is included in at least one implementation of the present disclosure. Thus, appearances of the phrase “in an implementation”, “in one implementation”, “in another implementation”, and similar language throughout this specification may, but do not necessarily, all refer to the same implementation.

The terms “comprise”, “comprising”, or any other variations thereof, are intended to cover a non-exclusive inclusion, such that a process or method that comprises a list of steps does not include only those steps but may include other steps not expressly listed or inherent to such process or method. Similarly, one or more devices or sub-systems or elements or structures or components preceded by “comprises . . . a” does not, without more constraints, preclude the existence of other devices or other sub-systems or other elements or other structures or other components or additional devices or additional sub-systems or additional elements or additional structures or additional components.

The implementations herein and the various features and advantageous details thereof are explained more fully with reference to the non-limiting implementations that are illustrated in the accompanying drawings and detailed in the following description. Descriptions of well-known components and processing techniques are omitted so as to not unnecessarily obscure the implementations herein. Also, the various implementations described herein are not necessarily mutually exclusive, as some implementations can be combined with one or more other implementations to form new implementation. The term “or” as used herein, refers to a non-exclusive or unless otherwise indicated. The examples used herein are intended merely to facilitate an understanding of ways in which the implementation herein can be practiced and to further enable those skilled in the art to practice the implementation herein. Accordingly, the examples should not be construed as limiting the scope of the implementation herein.

Implementation may be described and illustrated in terms of blocks that carry out a described function or functions. These blocks, which may be referred to herein as units or modules or the like, are physically implemented by analog or digital circuits such as logic gates, integrated circuits, microprocessors, micro-controllers, memory circuits, passive electronic components, active electronic components, optical components, hardwired circuits, or the like, and may optionally be driven by firmware and software. The circuits may, for example, be implemented in one or more semiconductor chips, or on substrate supports such as printed circuit boards and the like. The circuits constituting or included in a block may be implemented by dedicated hardware, or by a processor (e.g., one or more programmed microprocessors and associated circuitry), or by a combination of dedicated hardware to perform some functions of the block and a processor to perform other functions of the block. Each block of the implementation may be physically separated into two or more interacting and discrete blocks without departing from the scope of the present disclosure. Likewise, the blocks of the implementation may be physically combined into more complex blocks without departing from the scope of the present disclosure.

The accompanying drawings are used to help easily understand various technical features and it should be understood that the implementation presented herein is not limited by the accompanying drawings. As such, the present disclosure should be construed to extend to any alterations, equivalents, and substitutes in addition to those which are particularly set out in the accompanying drawings. Although the terms first, second, etc. may be used herein to describe various elements, these elements should not be limited by these terms. These terms are generally only used to distinguish one element from another.

An object of some example embodiments is to provide a device (particularly, a system level architecture design) for improving or optimizing noise at an output of a high voltage Low-Dropout (LDO) regulator or a converter.

Alternatively or additionally, an object of some example embodiments is to provide an input reference for the converter or the LDO that is selected to be at a higher intermediate voltage than a bandgap reference of 1.2V such that a feedback ratio of a final converter/LDO is reduced or minimized.

Alternatively or additionally, yet another object of some example embodiments is to introduce additional circuitry (e.g., a startup circuit) to reduce or minimize startup time of the final converter/LDO.

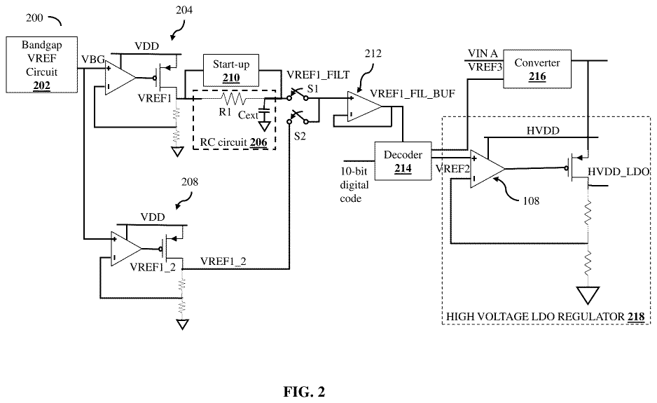

FIG. 2 illustrates a circuit diagram of the device 200 for improving or optimizing noise at an output of the high voltage LDO regulator 218, in accordance with some example embodiments.

In some example embodiments, the device 200 may include a first intermediate LDO regulator 204 configured to generate a first enhanced reference voltage (VREF1) based on an input reference voltage (VBG). The device 200 may also include a resistor-capacitor (RC) circuit 206 connected to the first intermediate LDO regulator 204. The RC circuit 206 may include an RC filter configured to generate a filtered reference voltage (VREF1_FILT) based on the first enhanced reference voltage (VREF1). The VREF1_FILT, which may be a filtered reference. The device 200 may further include a second intermediate LDO regulator 208 connected in parallel to the first intermediate LDO regulator 204 and the RC circuit 206. In some example embodiments, the second intermediate LDO regulator 208 may be a replica of the first intermediate LDO regulator 204. The second intermediate LDO regulator 208 may generate a second replica enhanced reference voltage (VREF1_2) based on the input reference voltage (VBG).

Further, the device 200 may include a low noise buffer 212 configured to selectively receive one of the filtered reference voltage (VREF1_FILT) or the second replica enhanced reference voltage (VREF1_2) to generate a buffer reference voltage (VREF1_FILT_BUF) for the high voltage LDO regulator 218. The one of the filtered reference voltage (VREF1_FILT) or the second replica enhanced reference voltage (VREF1_2) may be transmitted to the high voltage LDO regulator 218 based on an operational state of the RC filter. The operational state of the RC filter may include one or more of a start-up state, a settling state, or a settled state. The high voltage LDO regulator may be configured to generate the output (HVDD_LDO) based on the buffer reference voltage (VREF1_FILT_BUF).

In some example embodiments, the device 200 may include a bandgap voltage reference circuit 202 configured to provide the input reference voltage (VBG) to the first and second intermediate LDO regulators 204, 208.

In some example embodiments, the RC filter may be a low pass filter for filtering noise. In some example embodiments, the RC filter may include an internal resistor R1 and an external capacitor Cext. In some example embodiments, a value of R1 may be 200 KQ2, and a value of the Cext may be 10 μF, and the R1 and the Cext may provide filtering of noise from the bandgap circuit 202 and the first intermediate LDO regulator 204. In some example embodiments, the operational state of the RC filter may include one or more of the start-up state, the settling state, and the settled state. In some example embodiments, the start-up state of the RC filter may refer to a behavior of the filter immediately after a change in input of intermediate LDO 204, such as when an input signal is introduced (Bandgap 202 is powered ON and intermediate LDO 204 is enabled). During the start-up state, the Cext in the filter begins charging or discharging through the resistor R1, and the voltage across the Cext changes over time until the filter reaches its steady-state condition. The settling state of the RC filter may refer to a point in time when the filter is reaching a stable condition after switching ON the intermediate LDO 204. The settled state of the RC filter may refer to a condition where the filter has fully transitioned from a transient phase (i.e., initial charging/discharging of the Cext) and has reached a stable, steady output.

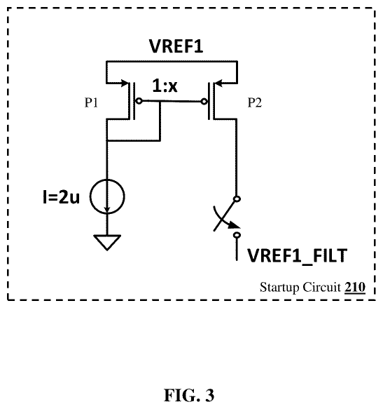

In some example embodiments, the RC circuit 206 may include a startup circuit 210 connected parallel to the internal resistor R1 of the RC filter. The startup circuit 210 may be configured to reduce a transitional time between the startup state and the settled state of the RC filter. In some example embodiments, the startup circuit 210 may include a current mirror circuit, which is explained in detail in conjunction with FIG. 3 in the forthcoming paragraphs.

In some example embodiments, the RC circuit 206 may be connected to the low noise buffer 212 via a first switch S1, and the second intermediate LDO regulator 208 may be connected to the low noise buffer 212 via a second switch S2. The first switch S1 and the second switch S2 may be operated based on the operational state of the RC filter. In some example embodiments, the first switch S1 may be turned off and the second switch S2 may be turned on during the startup state and the settling state of the RC filter, and the first switch S1 may be turned on and the second switch S2 may be turned off during the settled state of the RC filter. In some example embodiments, each of or at least one of the first switch S1 and the second switch S2 may be embodied as transistors, such as but not limited to n-type MOSFET transistors; however, example embodiments are not limited thereto.

In some example embodiments, the device 200 may also include a decoder 214. The decoder 214 may be connected to an output of the low noise buffer 212. The decoder 214 may generate an output (VREF2) that provides an input reference to the high voltage LDO regulator 218. The output VREF2 may be generated based on the VREF1_FILT_BUF and a 10-bit digital code (OUTPUT_CODE<9:0>). The 10-bit digital code may determine a desired HVDD_LDO value required at or expected at an output of the high voltage LDO regulator 218. Another output of the decoder 214 may be connected to an input reference of the converter 216.

In some example embodiments, a value of the VREF1 may be selected such that a closed loop voltage gain of the high voltage LDO 218 is reduced or minimized (e.g., Bhv_Ido is increased or maximized). The value of the VREF1 may also be selected depending upon the availability of a core power supply voltage (VDD). In some example embodiments, the value VREF2 may be programmable, e.g., may be dynamically determined.

In some example embodiments, to get lowest integrated noise at the high voltage LDO 218 (e.g. HVDD_LDO=17V), the VDD may be selected as 5.5 V, the VREF1 may be selected 5.3V, the VREF2 may be 5.25 V, thereby resulting in the closed loop voltage gain of 3.238 (i.e., (Bhv_ldo) of 0.308)), as compared to a conventional architecture that may have the closed loop voltage gain of 14.17 ((Bhv_Ido) would be 0.07). In some example embodiments, the value of Cext may be reduced (for example, by converting to internal capacitor), however, for this, the first intermediate LDO regulator 204 and the bandgap circuit 202 should be made low noise.

In some example embodiments, the second intermediate LDO regulator 208 and the startup circuit 210 may ensure a quick bring-up of the buffer reference voltage (VREF1_FILT_BUF). The final high voltage LDO output (HVDD_LDO) may be made programmable covering the range 5.25V-17V with the help of the decoder 214.

FIG. 3 illustrates the startup circuit 210, in accordance with some example embodiments. The startup circuit 210 includes the current mirror circuit, which may refer to and/or may be or include an analog circuit designed to sense a reference current and generate one or more copies of the reference current, with same characteristics. The replicated current may be as stable as the reference current source. The replicated current may be the same as the reference current, or could be either multiple of (e.g., an integral multiple of) or fraction of (e.g., a whole fraction of) the reference current. As shown in FIG. 3, the current mirror circuit may include two p-channel metal-oxide semiconductor (PMOS) transistors P1, P2, where the P1 may be the input transistor and the P2 may be the output transistor. The current mirror circuit may be configured as a 1:x current mirror, where the current through the output transistor P2 may scaled by a factor of x relative to the reference current. In some example embodiments, a scaling factor x may be set to 3700. The current from the current mirror circuit may directly flow from a node VREF1 into a node VREF1_FILT via a switch bypassing the internal resistor R1 when the switch is ON. The implementation of the switch may include at least one of a p-channel MOS (PMOS) or an n-channel MOS (NMOS) transistors; example embodiments are not limited thereto.

While the internal resistor R1 and the external capacitor Cext of the RC circuit 206 filter the noise of the bandgap circuit 202 and the first intermediate LDO regulator 204, a large time constant of the RC filter may result in a significant settling time for the VREF1_FILT node. For example, with R1=200KQ and Cext=10 μF, the settling time of the VREF1_FILT node may be approximately 2 seconds. To reduce the settling time, some example embodiments may include the startup circuit 210. The startup circuit 210 bypasses the R1 and supplies current to the VREF1_FILT node until the VREF1_FILT node reaches a desired voltage, after which the startup circuit 210 is disabled. The startup circuit 210 may accelerate the settling time by around 100 times. However, achieving a startup time shorter than approximately 10 microseconds may not be feasible with the Cext of around 10 μF. The startup circuit 210 may reduce the setting time of the VREF1_FILT to 1.5 milliseconds (with R1=200KQ, Cext=10 μF). To ensure or help ensure that the VREF1_FILT_BUF node settles within 10 microseconds, the second intermediate LDO regulator 208 is added parallel to the first intermediate LDO regulator 204. While the VREF1_FILT node is charging to a desired voltage, the second intermediate LDO regulator 208 operates, reducing the overall settling time of the VREF1_FILT_BUF to approximately 10 microseconds.

Some example embodiments provide at least the following advantages:
The device of some example embodiments may be able to achieve, for example, about 4-times lesser integrated noise (0.1 Hz to 1 MHz) at the output of a given high voltage converter/LDO.
Alternatively or additionally, some example embodiments may have device operate such that filtered reference voltage is powered up with an additional circuit which helps in reducing the power on time of the chip.
Alternatively or additionally, the device according to at least some example embodiments may be applied to any high voltage Direct Current (DC)-DC converter (buck/boost/buck-boost)/high voltage LDO.

The various actions, acts, blocks, steps, or the like in the flow diagrams may be performed in the order presented, in a different order, or simultaneously. Further, in some implementation, some of the actions, acts, blocks, steps, or the like may be omitted, added, modified, skipped, or the like without departing from the scope of the present disclosure.

Unless otherwise defined, all technical and scientific terms used herein have the same meaning as commonly understood by one ordinary skilled in the art to which this present disclosure belongs. The system, methods, and examples provided herein are illustrative only and not intended to be limiting.

While specific language has been used to describe the present subject matter, any limitations arising on account thereto, are not intended. As would be apparent to a person in the art, various working modifications may be made to the method to implement the concept as taught herein. The drawings and the forgoing description give examples of implementation. Those skilled in the art will appreciate that one or more of the described elements may well be combined into a single functional element. Alternatively, certain elements may be split into multiple functional elements. Elements from one implementation may be added to another implementation.

The implementation disclosed herein can be implemented using at least one hardware device and performing network management functions to control the elements.

While the detailed description herein contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing description of the specific implementation will so fully reveal the general nature of the implementation herein that others can, by applying current knowledge, readily modify and/or adapt for various applications such specific implementation without departing from the generic concept, and, therefore, such adaptations and modifications should and are intended to be comprehended within the meaning and range of equivalents of the disclosed implementation. It is to be understood that the phraseology or terminology employed herein is for the purpose of description and not of limitation. Therefore, while the implementation herein have been described in terms of preferred implementation, those of ordinary skill in the art will recognize that the implementation herein can be practiced with modification within the scope of the implementation as described herein. Additionally or alternatively, example embodiments are not necessarily mutually exclusive with one another. For example, some example embodiments may include one or more features described with reference to one or more figures, and may also include one or more other features described with reference to one or more other figures.

We claim:

1. A device for improving upon noise at an output of a high voltage Low-Dropout (LDO) regulator, the device comprising:
a first intermediate LDO regulator configured to generate a first enhanced reference voltage based on an input reference voltage;
a resistor-capacitor (RC) circuit connected to the first intermediate LDO regulator, wherein the RC circuit comprises an RC filter configured to generate a filtered reference voltage based on the first enhanced reference voltage;
a second intermediate LDO regulator connected in parallel to the first intermediate LDO regulator and the RC circuit, wherein the second intermediate LDO regulator is configured to generate a second replica enhanced reference voltage based on the input reference voltage; and
a low noise buffer configured to selectively receive one of the filtered reference voltage or the second replica enhanced reference voltage and to generate a buffer reference voltage for the high voltage LDO regulator, wherein
one of the filtered reference voltage or the second replica enhanced reference voltage is transmitted to the high voltage LDO regulator based on an operational state of the RC filter,
the operational state of the RC filter includes one or more of a start-up state, a settling state, or a settled state, and
the high voltage LDO regulator is configured to generate the output based on the buffer reference voltage.

2. The device as claimed in claim 1, further comprising:
a bandgap voltage reference circuit configured to provide the input reference voltage to the first and second intermediate LDO regulators.

3. The device as claimed in claim 1, wherein the RC filter includes a low pass filter configured to filter noise.

4. The device as claimed in claim 1, wherein the RC filter comprises an internal resistor and an external capacitor.

5. The device as claimed in claim 1, wherein
the RC circuit comprises a startup circuit connected parallel to an internal resistor of the RC filter, and
the startup circuit is configured to reduce a transitional time between the start-up state and the settled state of the RC filter.

6. The device as claimed in claim 1, further comprising:
a startup circuit connected in parallel to the RC circuit, the startup circuit comprising a current mirror circuit.

7. The device as claimed in claim 1, wherein
the RC circuit is configured to be connected to the low noise buffer via a first switch,
the second intermediate LDO regulator is configured to be connected to the low noise buffer via a second switch, and
the first switch and the second switch are configured to be operated based on the operational state of the RC filter.

8. The device as claimed in claim 7, wherein
the first switch is configured to be turned off and the second switch is configured to be turned on during the start-up state and the settling state of the RC filter, and
the first switch is configured to be turned on and the second switch is configured to be turned off during the settled state of the RC filter.

9. The device of claim 1, further comprising:
a decoder having an input connected to an output of the low noise buffer and having a first output connected to a first input of the high voltage LDO regulator.

10. The device of claim 9, wherein the decoder is configured to operate based on a 10-bit digital code.

11. The device of claim 9, further comprising:
a converter having a first input connected to a second output of the decoder, and having an output connected to a second input of the high voltage LDO regulator.

12. The device of claim 7, wherein at least one of the first switch or the second switch is a transistor.

13. The device of claim 6, wherein the current mirror is configured to operate with 2uA.

14. The device of claim 1, wherein each of the first intermediate LDO regulator and the second intermediate LDO regulator include an operational amplifier.

15. A method of operating a high voltage Low-Dropout (LDO) regulator, the method comprising:
generating a first enhanced reference voltage based on an input reference voltage;
generating a filtered reference voltage based on the first enhanced reference voltage by using a resistor-capacitor (RC) filter;
generating a second replica enhanced reference voltage based on the input reference voltage;
selectively receiving, by a low noise buffer, one of the filtered reference voltage or the second replica enhanced reference voltage, and
generating a buffer reference voltage for the high voltage LDO regulator;
transferring one of the filtered reference voltage or the second replica enhanced reference voltage to the high voltage LDO regulator based on an operational state of the RC filter, the operational state of the RC filter including one or more of a start-up state, a settling state, or a settled state; and
generating an output based on the buffer reference voltage.

16. The method of claim 15, further comprising:
providing the input reference voltage to first and second LDO regulators included in the high voltage LDO regulator.

17. The method of claim 15, further comprising:
filtering noise through the RC filter.

18. The method of claim 15, further comprising:
reducing a transitional time between the start-up state and the settled state.

19. The method of claim 15, further comprising:
turning off a first switch included in the high voltage LDO regulator to disconnect the RC filter from the low noise buffer and turning on a second switch included in the high voltage LDO regulator to connect an intermediate LDO regulator to the low noise buffer during the start-up state of the RC filter; and
turning on the first switch to connect the RC filter to the low noise buffer and turning off the second switch to disconnect the intermediate LDO regulator to the low noise buffer during the settled state of the RC filter.

20. A device for providing a regulated voltage, the device comprising:
a first intermediate LDO regulator configured to generate a first enhanced reference voltage based on an input reference voltage;
a resistor-capacitor (RC) circuit connected to the first intermediate LDO regulator, wherein the RC circuit comprises an RC filter configured to generate a filtered reference voltage based on the first enhanced reference voltage;
a second intermediate LDO regulator connected in parallel to the first intermediate LDO regulator and the RC circuit, wherein the second intermediate LDO regulator is configured to generate a second replica enhanced reference voltage based on the input reference voltage;
a low noise buffer configured to selectively receive one of the filtered reference voltage or the second replica enhanced reference voltage and to generate a buffer reference voltage; and
a high voltage Low-Dropout regulator configured to receive the buffer reference voltage as an input and generate the regulated voltage as an output based on the buffer reference voltage.
